(19) United States
(12) Patent Application Publication
(10) Pub. No.: US 2013/0270744 A1
(43) Pub. Date: Oct. 17, 2013

(54) SYSTEM AND METHOD FOR REMOVING COATING FROM AN EDGE OF A SUBSTRATE

(71) Applicant: FIRST SOLAR, INC., Perrysburg, OH (US)

(72) Inventors: Michael Catalano, Toledo, OH (US); Stephen P. Murphy, Perrysburg, PA (US); Roland Mayerhofer, Roettenbach (DE)

(73) Assignee: First Solar, Inc., Perrysburg, OH (US)

(21) Appl. No.: 13/840,081

(22) Filed: Mar. 15, 2013

Related U.S. Application Data
(63) Continuation of application No. 12/887,161, filed on Sep. 21, 2010.

(51) Int. Cl. H01L 21/64

(52) U.S. Cl. CPC H01L 21/64
USPC 264/400; 425/174.4

(57) ABSTRACT

A coating-removal apparatus may include a source positioned on a mounting plate, and operable to emit a laser beam at a first path, where the mounting plate is configured to receive an edge of a photovoltaic module in a designated region substantially proximate to the mounting plate, such that the first path intersects the designated region, and where the mounting plate is further configured to reposition the source to create an additional path that intersects with the designated region, where the additional path is distinct from the first path.

### RELATED APPLICATION DATA

This application is a continuation of U.S. Utility patent application Ser. No. 12/887,161, filed on Sep. 21, 2010, which claims priority under 35 U.S.C. §119(e) to U.S. Provisional Patent Application Ser. No. 61/244,519 filed on Sep. 22, 2009, both of which are hereby incorporated by reference.

### TECHNICAL FIELD

The present invention relates to photovoltaic devices and methods of production.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices can also contain one or more transparent conductive oxide layers, which are also often conductors of electrical charge.

### DESCRIPTION OF DRAWINGS

FIG. 1A is a schematic of a system for deleting material from a photovoltaic module.

FIG. 1B illustrates a portion of a coating layer deleted from a photovoltaic module.

FIG. 2 is a schematic of a system for deleting material from a photovoltaic module.

FIG. 3 is a schematic of a system for deleting material from a photovoltaic module.

FIG. 4 is a schematic of a photovoltaic module.

FIG. 5 is a schematic of a system for deleting material from a photovoltaic module.

### DETAILED DESCRIPTION

A photovoltaic device can include a transparent conductive oxide layer adjacent to a substrate and one or more layers of semiconductor material. For example, the layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power.

Portions of semiconductor material and other coatings can be deleted from the edges of photovoltaic modules, which may comprise a series of connected photovoltaic devices. For example, industry requirements dictate that photovoltaic modules maintain a minimum non-conductive width around their perimeters. Traditional methods of deleting coating from photovoltaic modules have required the use of mechanical brushes. Though adequate for removing unwanted material, brushes have a tendency to wear, causing a number of problems, including non-uniformity in the coating-removal process, downtime for maintenance, and recurring replacement costs. An alternative is to forgo the use of mechanical brushes altogether and to remove the undesired material optically using laser scribing. Because photovoltaic modules may contain glass substrates, lasers are capable of penetrating the photovoltaic structure through the substrate layer to remove the unwanted coatings on the other side. The instant inventions relate to systems, devices, and methods for optically removing coatings from the edges of photovoltaic modules using laser technology.

A method for removing coating from a substrate can include directing a laser beam along a first path to a first position on a first surface of the substrate. The first position on the first surface can be proximate to the edge of the substrate at an angle of incidence suitable to redirect the laser beam along a second path. The second path can be through the substrate, and to a second position on a second surface of the substrate at the edge of the substrate. The second surface can include a coating. The method can include and ablating at least a portion of the coating at the second position on the second surface of the substrate.

The method can include various optional features. For example, directing a laser beam along a first path to a first position on a first surface can include directing the laser beam along the first path to a non-coated first position on a first surface of the substrate. Directing a laser beam along a first path to a first position on a first surface can include directing the laser beam along the first path toward a substantially flat first surface of the substrate. Ablating at least a portion of the coating can include removing a portion of the coating from a substantially flat surface. Ablating at least a portion of the coating can include removing a portion of the coating from a curved surface. The substrate can include glass. The glass can be soda lime glass. The method can include scanning the laser beam along a region proximate to the edge of the substrate. Directing the laser beam can include comparing a substrate refractive index, an external refractive index, a laser exit point, and any combination thereof to determine a laser entry point on the substantially flat non-coated side of the substrate and an angle of incidence to the normal plane; and directing a laser beam at the determined laser entry point at an angle corresponding to the angle of incidence, where the substrate refractive index defines a refractive medium within the substrate, the external refractive index defines a refractive medium outside of and adjacent to the substrate, and the laser exit point represents a location area on an edge of the substrate.

The method can include configuring a controller to compare a substrate refractive index identifier, an external refractive index identifier, a laser exit point identifier, and any combination thereof to determine a laser entry point on the substantially flat non-coated side and an angle of incidence to the normal plane, and to direct the laser source to emit a beam at the determined laser entry point at an angle corresponding to the angle of incidence, where the substrate refractive index identifier defines a refractive medium within the substrate, the external refractive index identifier defines a refractive medium outside of and adjacent to the substrate, and the laser exit point identifier represents a location area on an edge of the glass layer.

A coating-removal apparatus can include a laser source positioned on a mounting plate operable to provide a laser beam along a first path. The mounting plate can be configured to partially surround an edge of a photovoltaic module in a designated region, such that the first path intersects the designated region, and a positioner configured to reposition the mounting plate. The coating-removal apparatus can include a processor configured to identify a laser entry point on a non-coated side of a photovoltaic module, corresponding to a desired laser exit point on a coated edge of the photovoltaic module, and to direct the source to emit a laser beam at the determined laser entry point. The coating-removal apparatus can include a gap, such that two portions of the mounting plate lie partially separate and parallel from each other, and where the gap defines the designated region.

The coating-removal apparatus can include an actuator to which the mounting plate is mounted adjacent, and which is operable to adjust the mounting plate in a horizontal plane, a vertical plane, or both. The mounting plate can include a gap, such that two portions of the mounting plate lie partially separate and parallel from each other, and where the gap is configured to receive a photovoltaic module. The coating-removal device can be mounted along an edge of the gap. The coating-removal apparatus can include an actuator to which the mounting plate is mounted adjacent, and which is operable to adjust the mounting plate to a new position. The actuator can be operable to adjust the mounting plate in a horizontal plane, a vertical plane, or both.

A photovoltaic module can include: a substrate; and a semiconductor material on the substrate, where the edge of the substrate is substantially free of the semiconductor material and the substrate surface in the region free of semiconductor material is substantially free of surface erosion.

The photovoltaic module may include various optional features. For example, the semiconductor material can include a cadmium. The semiconductor material can include a silicon. The semiconductor material can include an amorphous silicon. The semiconductor material can include a compound semiconductor. The compound semiconductor can include a cadmium telluride.

A laser scribing apparatus can include a laser source that provides a pulsed laser beam with a wavelength at a near-infrared fundamental frequency and having a pulse frequency in the range of about 50 to about 100 kilohertz and a pulse duration in the range of about 8 to about 70 nanoseconds. The laser source can be a diode-pumped, Q-switched, neodymium-doped, yttrium vanadate laser source providing a pulsed laser beam with a wavelength at its near-infrared fundamental frequency of about 1064 nanometers and operating at a pulse frequency in the range of about 50 to about 100 kilohertz with the pulse duration in the range of about 8 to about 70 nanoseconds. The pulsed laser beam can be reflected by one or more mirrors to an XYZ galvanometer controlled mirror system that directs the laser beam to perform the scribing. More specifically, the XYZ galvanometer controlled mirror system can include a galvanometer controlled focuser that moves a lens horizontally to control the focal length of the beam in the Z direction and a galvanometer controlled dual mirror assembly that directs the beam in the XY directions so as to thereby collectively provide XYZ control.

The scribing can be performed by directing a laser beam through the uncoated surface of a substrate to its coated surface, and through to the different areas for the scribing, with the layers scribed being controlled by the power level of the laser for each of the scribes. By laser scribing of the scribes from the uncoated surface of the substrate, there is no gas plume formed by the ablations that provide the scribing such that the plumes cannot prevent the next laser pulses from passing through the coatings to provide each next ablation.

The laser scribing apparatus can include gas pressure and vacuum positioners that maintain the substrate planar at its uncoated surface and position the substrate laterally with respect to the direction of conveyance so the focused pulsed laser beam has its focus in the Z direction at the layer or layers being scribed. These positioners are located in vertically extending sets both upstream and downstream of the location where the laser beam passes through the glass sheet substrate to provide the laser scribing. There can be five of the positioners upstream of the scribing location and five of the positioners downstream of the scribing location. Each of the positioners can have a central location to which a vacuum is applied from a vacuum source through an associated conduit. An annular porous member of each positioner can extend around the location and receive pressurized gas from a gas source through an associated conduit. The positioners can position the uncoated glass sheet surface within about 4 to about 6 microns so as to provide an accurate location for the laser beam focusing and the ablations at the layer or layers being scribed.

Laser detectors located upstream from the scribing location can provide laser detection beams that are reflected back from the uncoated surface to detect the exact position of the substrate, and through connection to the focuser of the galvanometer mirror system focus the pulsed scribing laser beam in response to the position detected throughout the range of movement and scribing of the scribing laser beam. This detection can accommodate for any nonplanarity of the substrate such as roller waves formed when a glass substrate is manufactured.

The laser scribing station conveyor can provide a conveying index between each laser scribe during which the coated substrate is held stationary such that the laser beam moves vertically to perform the scribing, after first having been adjusted horizontally to provide the proper spacing between the previously formed adjacent scribe. It is also possible for the coated substrate to be continuously conveyed along the direction of conveyance, and the path of the laser scribes is then angular both along the direction of conveyance and with respect to a true vertical direction, and after the completion of each scribe, there is a reset motion of the galvanometer controlled mirror system such that the complete pass has a generally bow tie configuration.

Prior to conveyance to the first scribing station, the two upper corners of the coated substrate are laser marked with respective fiducials which are detected by a pair of cameras so as to provide a signal for accurate location of the panel and the spacing between the fiducials so that the scribing can be accurately located. This allows adjustment as necessary for thermal expansion or contraction and for different spacings between the fiducials on different substrates. In addition, each substrate can be provided with a bar code that is sensed by a bar code reader so as to provide identification of each particular substrate being scribed. In addition, the apparatus includes an exhaust hood that receives the exhaust from the coated side of the substrate being scribed. To insure that the scribing is performed at the proper power level, the galvanometer controlled mirror can periodically reflect the laser beam to a power meter whose sensed power can then be utilized to provide any necessary adjustment of the power level from the pulsed laser source. In order to provide the first, second, and third sets of the scribes through the different layers, the average power levels of the lasers are respectively about 20 watts, about 8 to 9 watts, and about 4 to 5 watts.

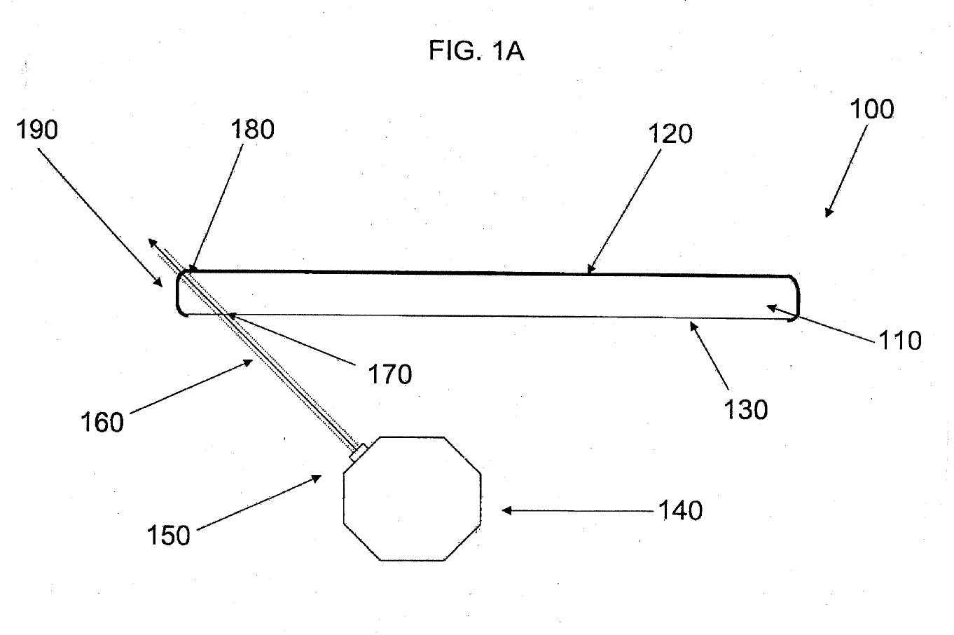

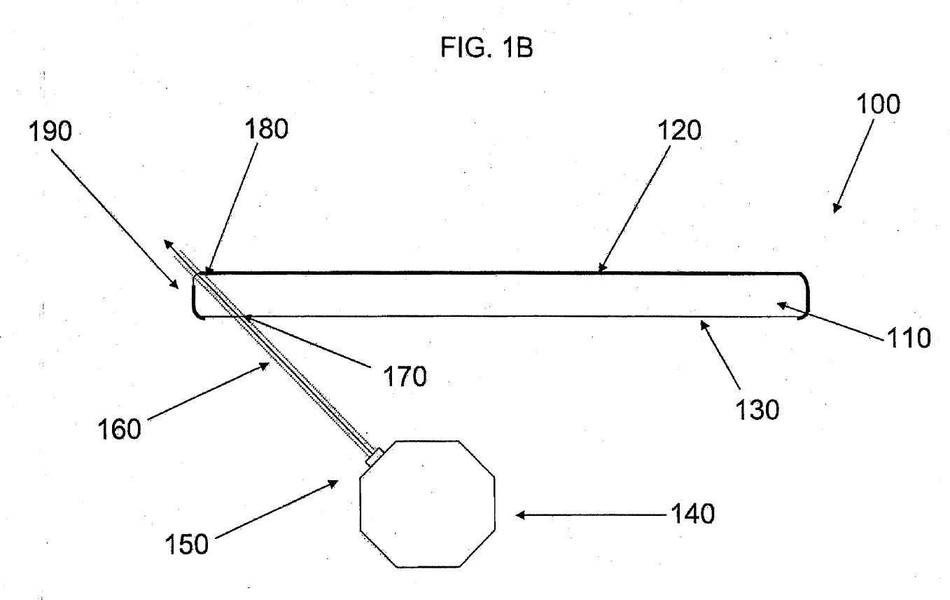

Referring to FIG. 1A, a system for deleting portions of coating layer 120 from a photovoltaic module 100 can include a source 150 operable to emit a laser beam 160. Source 150 can be a part of coating-removal device 140. Coating-removal device 140 can direct laser beam 160 via laser source 150 toward photovoltaic module 100 at an angle of emission. In one embodiment of the system, coating-removal device 140 directs laser beam 160 toward a facially exposed, substantially flat non-coated (or otherwise able to pass the laser beam wavelength) side 130 of substrate 110 at laser entry point 170. Substrate 110 can include a glass. Laser beam 160 travels through substrate 110 and exits through an edge 190 at laser exit point 180, thereby deleting the portion of coating layer 120 on edge 190 at laser exit point 180, as depicted in FIG. 1B. Edge 190 can include a top edge of substrate 110, a side of substrate 110, and/or a bottom edge of substrate 110. Edge 190 can be partially rounded. Edge 190 can be partially, substantially, or completely coated. Substantially flat non-coated side 130 can contain some portion of coating. For example, substantially flat non-coated side 130 can include a portion of coating proximate to edge 190.

Coating layer 120 can include any suitable coating material for the fabrication of photovoltaic modules, and can consist of multiple layers. For example, coating layer 120 can include a cadmium or a silicon. Coating layer 120 can include an amorphous silicon. Coating layer 120 can include a compound semiconductor material. For example, coating layer 120 can include a cadmium telluride layer and/or a cadmium sulfide layer. Coating-removal device 140 can be configured to remove some or all of coating layer(s) 120 from substrate 110.

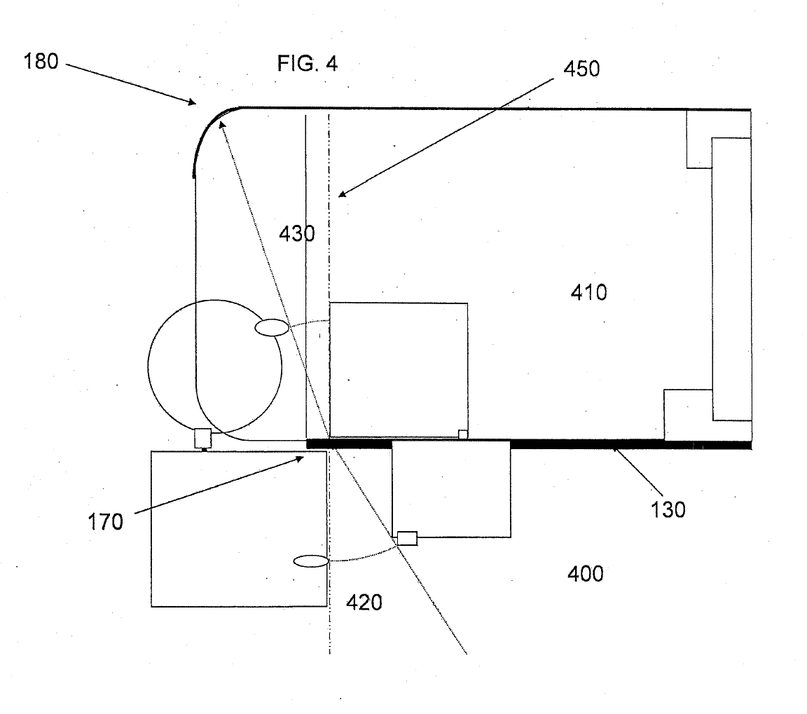

The path of laser beam 160 through substrate 110 can be calculated. Referring to FIG. 4 by way of example, laser beam 160 enters substantially flat non-coated side 130 of substrate 110 at laser entry point 170 at angle of incidence 420 relative to normal 450. The refractive index 410 of substrate 110 differs from the external refractive index 400 outside photovoltaic module 100, altering the speed, angle, and path of laser beam 160 once it passes through substrate 110. Laser beam 160 extends through glass layer 110 at angle of refraction 430, relative to normal 450, to laser exit point 180. The angle of refraction 430 is relatable to the angle of incidence 420 by the following: n₁*sin θ₁=n₂*sin θ₂, where n₁ defines the external refractive index 400, n₂ defines the substrate refractive index 410, θ₁ defines the angle of incidence 420, and θ₂ defines the angle of refraction 430. The refractive indices can thus be used to trace and predict laser exit point 180 of laser beam 160, allowing for strategic placement of the photovoltaic module relative to the position and angle of the laser.

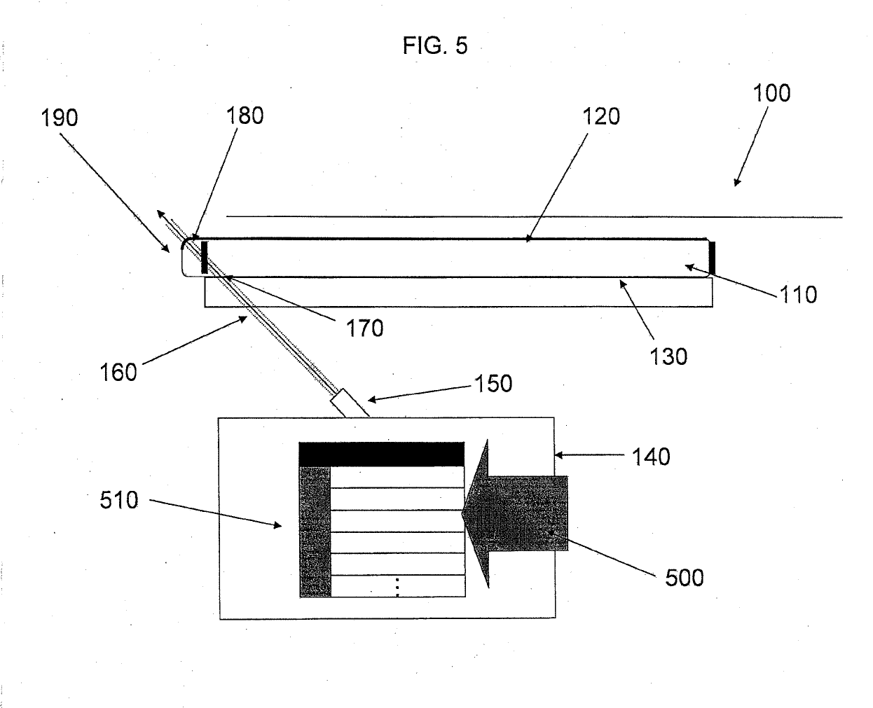

The path of laser beam 160 can be calculated through external means, allowing for coating-removal device 140 to be positioned accordingly. Or coating-removal device 140 can perform the calculations autonomously. Referring to FIG. 5 by way of example, in one embodiment, coating-removal device 140 can include a microprocessor 510 in communication with a source 150. Microprocessor 510 can be operable to store information necessary for the determination of the path of laser beam 160 through glass layer 110. For example, microprocessor 510 can store values for each of substrate refractive index 410, external refractive index 400, angle of incidence 420, angle of refraction 430, laser entry point 170, and laser exit point 180 (from FIG. 4). Microprocessor 510 can also receive information via data interface 500. Accordingly, microprocessor 510 can be pre-programmed with laser path data, or it can receive the data from an alternate source. Microprocessor 510 can be configured to calculate a preferred path for laser beam 160 using the laser path data. For example, a location area on edge 190 containing unwanted coating can be targeted by tracing laser exit point 180 back to substantially flat non-coated side 130 to obtain a desired angle of refraction 430 and laser entry point 170. Using the refractive indices, the theoretical angle of incidence 420 is given by: θ₁=sin⁻¹ ((n₂/n₁)*sin θ₂). Calculated angle of incidence 420 can be communicated from microprocessor 510 to source 150 to effectuate a proper angle for laser beam 160 to remove a portion of coating layer 120 from edge 190. Data can be input into microprocessor 510 manually or autonomously through sensory equipment.

An alternative embodiment could involve external calculation of the entry points, exit points, angles of incidence and refraction, and any combination thereof. For example, instead of coating-removal device 140 containing microprocessor 510, coating-removal device 140 could comprise almost entirely of an adjustable laser source, as in FIG. 1A. The calculations for the desired laser entry point 170 and the angle of incidence 420 could be executed externally by another device or a person. Coating-removal device 140 could then be manually adjusted to achieve the desired effect. Coating-removal device 140 can also be adjusted to alter the wavelength, power, speed, pulse frequency, and/or duration of laser beam 160 to facilitate removal of different layers of coating. For example, coating-removal device 140 can be adjusted to emit an infrared frequency.

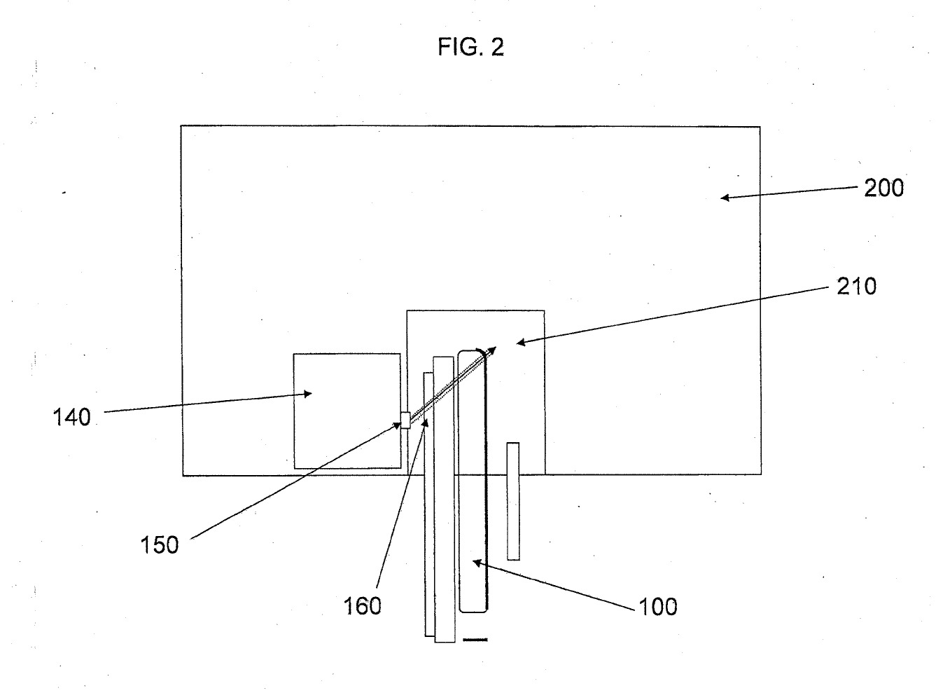

Referring now to FIG. 2, coating-removal device 140 can be mounted adjacent to mounting plate 200. Mounting plate 200 can include a gap 210. Gap 210 can partially separate two portions of mounting plate 200, such that they lie partially separate and parallel. Gap 210 can be configured to receive a photovoltaic module 100. Coating-removal device 140 can be mounted along an edge of gap 210. Referring to FIGS. 1A and 2, coating-removal device 140 can delete a portion of coating layer 120 from photovoltaic module 100 via the laser beam 160 emitted from laser source 150 once photovoltaic module 100 is received in gap 210. Photovoltaic module 100 can be positioned or passed through gap 210 in any suitable fashion to permit removal of undesired coating.

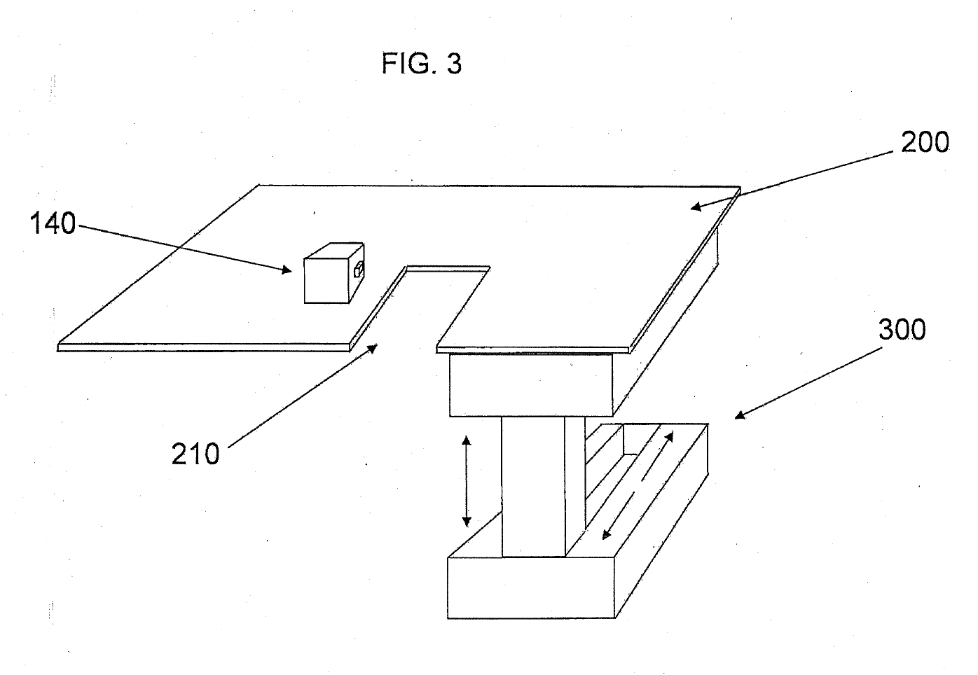

Referring now to FIG. 3, a mounting plate 200 can be mounted adjacent to an actuator 300. Actuator 300 can be configured to shift mounting plate 200 in the horizontal direction, the vertical direction, or both. Referring to FIGS. 1A and 3, actuator 300 can be configured to adjust mounting plate 200 to a new position to allow coating-removal device 140 to direct laser beam 160 via laser source 150 at a different location on glass layer 110 of photovoltaic module 100. Referring to FIGS. 3 and 4 by way of example, adjustment of mounting plate 200 can cause laser entry point 170, laser exit point 180, angle of incidence 420, or any combination thereof to change, permitting laser beam 160 to remove a different section of coating layer 120 from edge 190. Repositioning of photovoltaic module 100 within gap 210 can also affect change to laser entry point 170, laser exit point 180, or angle of incidence 420. The directional arrows depicted in FIG. 3 with relation to mounting plate 200 and actuator 300 are in no way limiting. For example, actuator 300 can be configured to adjust mounting plate 200 in the X, Y, and/or Z planes.

Photovoltaic devices/modules fabricated using the methods discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method for scribing a coated surface, comprising:
providing a substrate having at least one coated surface and at least one uncoated surface;
directing a laser beam to at least one entry point on the uncoated surface;
passing the laser beam through the substrate from the entry point to at least one portion of the coated surface; and,
scribing at least one portion of the coated surface with the laser beam, wherein the step of scribing comprises controlling at least one property of the laser beam to facilitate scribing of the layer of coating.

2. The method of claim 1, wherein the at least one property of the laser beam comprises at least one of the wavelength, power, speed, pulse frequency, or duration of the laser beam.

3. The method of claim 1, wherein the step of passing the laser beam through the substrate comprises passing the laser beam from the entry point to at least one exit point on the portion of the coated surface to be scribed, wherein the entry point, exit point, and a hypothetical normal to the entry point define an angle of refraction.

4. The method of claim 3, wherein the at least one property of the laser beam comprises at least one of the entry point, exit point, or angle of refraction of the laser beam.

5. A method for removing coating from an edge of a substrate, comprising:
providing a substrate having at least one coated surface and at least one uncoated surface;
directing a laser beam to at least one entry point on the uncoated surface;
passing the laser beam through the substrate from the entry point to at least one portion of an edge of a coated surface; and,
removing at least a portion of a coating on the edge of the coated surface with the laser beam, wherein the step of removing comprises controlling the power level of the laser beam.

6. The method of claim 5, further comprising reflecting the laser beam to a power meter, sensing the power level of the laser beam with the power meter, comparing the sensed power level to a prescribed power level for removing the at least one portion of edge coating, and adjusting the power level of the laser beam.

7. The method of claim 5, wherein the step of passing the laser beam through the substrate comprises passing the laser beam from the entry point to at least one exit point in the at least one portion of the edge coating to be removed, wherein the entry point, exit point, and a hypothetical normal to the entry point define an angle of refraction.

8. The method of claim 7, wherein the step of removing further comprises controlling at least one of the entry point, exit point, or angle of refraction of the laser beam.

9. The method of claim 8, wherein directing the laser beam comprises:
comparing any combination of a refractive index of the substrate, an external refractive index created by a refractive medium outside of and adjacent to the substrate, and a preselected exit point on the substrate;
determining the entry point and an angle of incidence to the entry point based on the compared data; and,
directing a laser beam at the entry point at the angle of incidence.

10. The method of claim 5, wherein the laser beam is generated by a laser source, and the method further comprises adjusting a position of at least one of the substrate and laser source in at least one of a horizontal direction and a vertical direction.

11. The method of claim 5, wherein no gas plume is formed during the removing step.

12. A device for removing a coating from an edge of a substrate, comprising:
a laser source which emits a laser beam, wherein the laser source is configured to direct the laser beam to at least one entry point on an uncoated surface of a substrate, though the substrate, and to at least one portion of a coating on an edge of the coated surface of the substrate; and,
a controller configured to control the laser beam.

13. The device of claim 12, wherein the controller is configured to control at least one of the wavelength, power, speed, pulse frequency, or duration of the laser beam.

14. The device of claim 13, wherein the controller is configured to adjust the power of the laser beam.

15. The device of claim 12, wherein the path of the laser beam through the substrate defines at least one exit point on the at least one portion of the coated edge, wherein the entry point, exit point, and a hypothetical normal to the entry point define an angle of refraction.

16. The device of claim 15, wherein the controller is configured to adjust at least one of the entry point, exit point, or angle of refraction of the laser beam.

17. The device of claim 12, further comprising:
a means for comparing any combination of a refractive index of the substrate, an external refractive index created by a refractive medium outside of and adjacent to the substrate, and a preselected exit point on the substrate;
a means for determining the entry point and an angle of incidence to the entry point based on the compared data.

18. The device of claim 12, further comprising a means for adjusting a position of at least one of the substrate and laser source, in at least one of a horizontal direction and a vertical direction.

19. The device of claim 12, further comprising an exhaust hood configured to receive exhaust from the at least one portion of the coated edge.

20. The device of claim 12, further comprising a power meter configured to sense the power level of the laser beam, a means for comparing the sensed power level to a prescribed power level and determining a required adjustment, and a means for communicating the required adjustment from the means for comparing to the controller.
